(19) United States
(12) Patent Application Publication
(10) Pub. No.: US 2011/0031537 A1
(43) Pub. Date: Feb. 10, 2011

(54) SENSOR ELEMENT OF A GAS SENSOR

(76) Inventors: Markus Widenmeyer, Schoenaich (DE); Dieter Elbe, Sachsenheim (DE)

Correspondence Address: KENYON & KENYON LLP, ONE BROADWAY, NEW YORK, NY, 10004, US

(21) Appl. No.: 12/735,517

(22) PCT Filed: Jan. 7, 2009
(86) PCT No.: PCT/EP2009/050103

§ 371 Date: Oct. 7, 2010

(30) Foreign Application Priority Data
Jan. 28, 2008 (DE) 102008006326.6

(51) Int. Cl. H01L 29/772; H01L 21/335

(52) U.S. Cl. 257/253; 438/49; 257/E29.242; 257/E21.4

(57) ABSTRACT

A sensor element of a gas sensor for determining gas components in gas mixtures is provided, which includes a field-effect transistor having a source electrode, a drain electrode, and a gate electrode. The gate electrode includes a gate metallization, which is in contact with an insulation layer or a semiconductor substrate of the field-effect transistor via a boundary layer, the boundary layer being formed by modifying the surface of the insulation layer or the semiconductor substrate using metal alkoxides, metal amides, metal halogenides and/or metal alkyls. Furthermore, a method for producing said sensor element is provided.

### FIELD OF THE INVENTION

The present invention relates to a sensor element of a gas sensor for determining gas components in gas mixtures, in particular in exhaust gases of internal combustion engines, and to a method for fabricating such a sensor element as well as to its use.

### BACKGROUND INFORMATION

Field-effect transistors, among other devices, are used for determining gas components in gas mixtures. In so doing, for example, the gate or the gate electrode of the field-effect transistor reacts in a sensitive manner to gas components to be determined, thereby causing a change in a control voltage applied at the gate electrode. The occurring change in the current flow that results between the source and the drain electrode of the field-effect transistor is detected and assigned to a concentration of the gas component to be determined.

Such a gas sensor is discussed in German patent document DE 10 2005 010 454 A1, for instance. The gate electrode has an acid or a basic coating, which increases the sensitivity of the gas sensor to combustion-relevant gases. It is disadvantageous that only pH-active gases can be detected. A determination of exhaust-gas components without any significant cross sensitivity to hydrocarbons is not possible.

The selectivity or sensitivity of such a sensor element implemented as field-effect transistor is the complex result of a plurality of factors such as the composition of individual components of the gate electrode. Among these factors are a gate metallization implemented in the form of a noble metal coating, or an insulation layer provided between the gate metallization and the semiconductor substrate.

### SUMMARY OF THE INVENTION

The exemplary embodiments and/or exemplary methods of the present invention are based on the objective of providing a sensor element for determining gas components in gas mixtures, the sensor element having a field-effect transistor that is especially sensitive to gas components to be determined as the result of a suitable boundary layer in the region of the gate electrode.

A sensor element or a sensor element produced with the aid of the claimed method and having the characterizing features described herein achieves the objective on which the exemplary embodiments and/or exemplary methods of the present invention is based in an advantageous manner. A field-effect transistor integrated into the sensor element has a gate electrode provided with a gate metallization, which is in contact with an insulation layer or a semiconductor substrate of the field-effect transistor via a boundary layer, the boundary layer being produced by modifying the surface of the insulation layer or the semiconductor substrate in a chemical manner. Particularly suitable for this purpose is a treatment with metal alkoxides, metal amides, metal halogenides or metal alkyls.

Further advantageous developments of the exemplary embodiments and/or exemplary methods of the present invention ensue from the further description herein.

For example, it is advantageous if the insulation layer is made of silicon nitride, which always has limited quantities of free Si—OH groups that are accessible to chemical modification. During the modification they react with the employed metal alkoxides, metal amides, metal halogenides or metal alkyls.

Furthermore, it is advantageous if the surface modification is performed by applying a titanium or germanium alkoxide. The mentioned alkoxides are easily hydrolyzed and form a stable and chemically inert layer composite during a subsequent heat treatment. The same holds true when dialkylamides or dimethylsilylamides of titanium or bisthmuth are used. An easily implementable surface modification for generating a boundary layer can also be expected when using tetraalkylgermanium compounds.

Furthermore, when using metal amides to generate the boundary layer, it is advantageous if the hydrolysis and dehydration of the applied metal amides is followed by a treatment with a mixture of a mineral acid in alcohol. This makes it possible to successfully dissolve remaining amines still contained in the surface coating.

The described sensor element is able to be used to advantage for determining gas components in exhaust gases of internal combustion engines, power plants or heating devices. Furthermore, it is advantageously suitable for checking the proper functioning of a NOx storage catalyst or an SCR exhaust-gas aftertreatment system.

An exemplary embodiment of the present invention is represented in the drawing and explained in greater detail in the following description.

### BRIEF DESCRIPTION OF THE DRAWINGS

FIG. 1 shows a schematic sectional view of a sensor element according to a first specific embodiment of the present invention.

FIG. 2 shows a schematic sequence of the method steps provided for in a chemical modification of the gate material.

### DETAILED DESCRIPTION

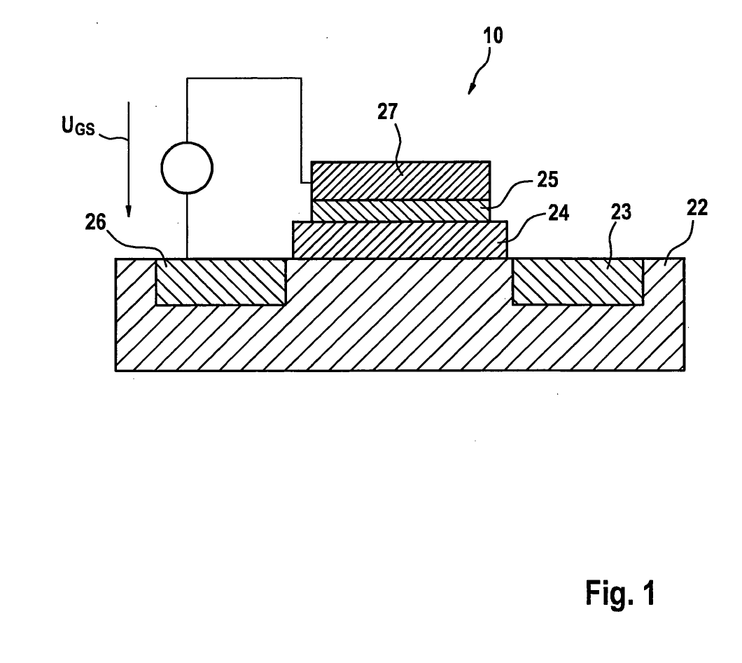

FIG. 1 shows a sensor element according to a first specific embodiment of the present invention. Sensor element 10 may be implemented as field-effect transistor (FET) or as chemically sensitive field-effect transistor (CHEMFET). Sensor element 10 in the form of a field-effect transistor includes a semiconductor substrate 22, which is implemented from gallium nitride, aluminum nitride, gallium aluminum nitride or silicon carbide, for instance. These materials are suitably doped in each case or, in the case of gallium nitride, for instance, include a layer made of gallium aluminum nitride having a thickness of a few nanometers. Semiconductor substrate 22 is provided with contact 26 of a source electrode and contact 23 of a drain electrode. In addition, sensor element 10 includes a gate metallization 27, which is in physical contact with semiconductor material 22 via an insulation layer 24 made of silicon nitride, for example. Insulation layer 24 prevents gate leakage currents and potential electro-migration. This ensures the electrical operation and allows a simple signal evaluation.

If gate metallization 27 is suitably sensitive to gas components to be measured, then the level of a voltage U_{GS} applied between contact 26 of the source electrode and gate metallization 27 changes as a function of the concentration of the gas component to be determined.

Furthermore, according to the exemplary embodiments and/or exemplary methods of the present invention, the sensitivity of the gate electrode formed by semiconductor substrate 22, insulation layer 24, and gate metallization 27 is able to be increased by providing a boundary layer 25 between insulation layer 24 and gate metallization 27. According to an alternative specific embodiment, it is also possible to dispense with a separate insulation layer 24. In this case, boundary layer 25 adjoins the material of semiconductor substrate 22 on the one side, and gate metallization 27 on the side lying opposite.

According to the exemplary embodiments and/or exemplary methods of the present invention, boundary layer 25 is produced by treating insulation layer 24 or semiconductor substrate 22 in a suitable manner with metal alkoxides, metal amides, metal halogenides and/or metal alkyls, in particular in the region of the gate. When treating the surface of insulation layer 24 or semiconductor substrate 22 with the mentioned metal compounds, a reaction of near-surface hydroxide groups of the materials of insulation layer 24 or semiconductor substrate 22 with the mentioned metal compounds occurs. If the surface of insulation layer 24 or semiconductor substrate 22 has insufficient density of near-surface hydroxide groups, then their number is able to be selectively increased by oxidative or hydrothermal methods. Furthermore, it is possible to use the more reactive metal alkyls or metal amides instead of the mentioned alkoxides, possibly at a higher temperature.

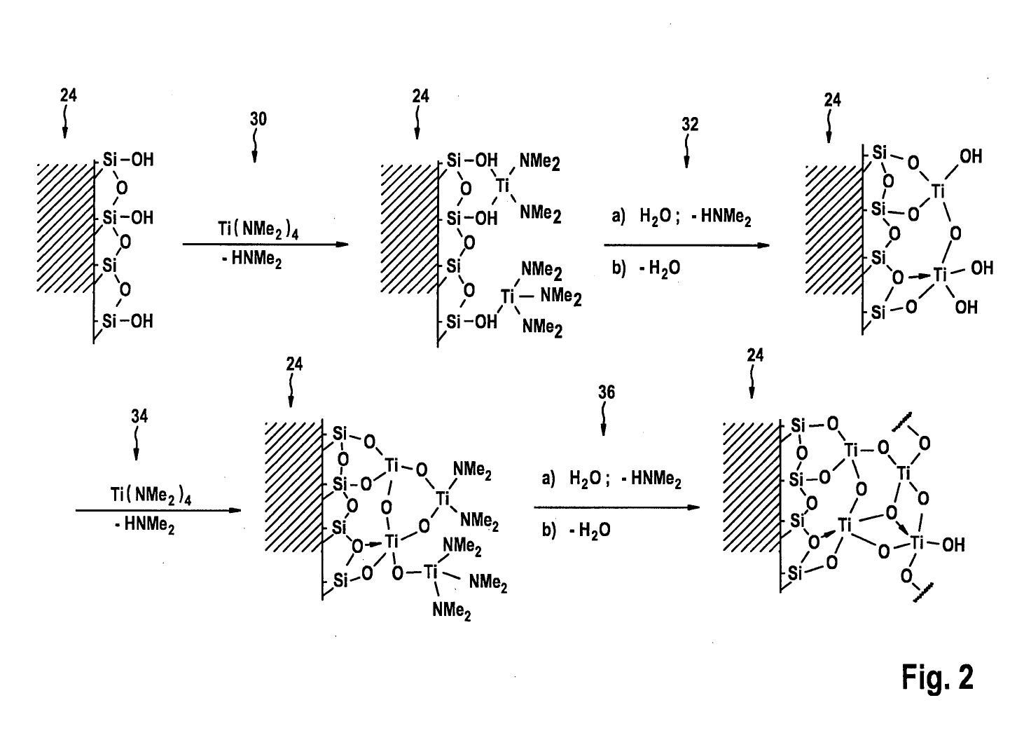

The method on which the layer design for generating boundary layer 25 is based is illustrated in FIG. 2. As an example, insulation layer 24 is provided with a boundary layer 25, but it is likewise also possible to apply a corresponding boundary layer 25 to semiconductor substrate 22 of the field-effect transistor.

To generate a boundary layer 25 on a large surface of insulation layer 24 of the field-effect transistor or its semiconductor substrate 22, its surface is treated with a metal alkoxide, a metal amide, a metal halogenide and/or a metal alkyl. In the process, the mentioned metal compounds react with free hydroxide groups at the surface of insulation layer 24 or semiconductor substrate 22. The processes taking place in this reaction are illustrated in FIG. 2 by way of example for the reaction of titanium tetra(dialkylamide), in the form of a first process step 30.

In the event that the number of hydroxide groups available at the surface of insulation layer 24 or semiconductor substrate 22 is insufficient, then the treatment with one of the mentioned metal compounds may be preceded by a pretreatment in the form of a high-temperature treatment in air or in a water vapor atmosphere.

The surface of insulation layer 24 or semiconductor substrate 22 modified with the aid of the mentioned metal compounds is first hydrolyzed in an additional process step 32, for example, followed by a dehydration reaction. This results in a metal oxide network containing hydroxide groups. This reaction scheme may basically be repeated any number of times, the layer thickness of produced boundary layer 25 being adjustable in selective manner by repeating process steps 30 and 32.

Metal alkoxides, for example, which may be in the form of titanium alkoxides such as titanium(diisopropyl oxide)dichloride or titanium tetrakis(isopropyl oxide) as well as germanium alkoxide such as tetra ethoxygermanium are suitable metal compounds. Furthermore, metal amides such as, e.g., titanium bisdialkylamide or titanium tetradialkylamide such as titanium tetra kis(diethylamide) or titanium tetrakis(dimethylamide) are suitable as metal compounds, as well as titanium bis(dimethylsilylamide), titanium tetra(dimethylsilylamide) or bismuth bis(trimethylsilylamide). Finally, metal alkyls such as tetraalkyl germanium compounds are suitable as metal compounds.

The method illustrated in FIG. 2 may be implemented according to the following exemplary embodiment, for example.

The surface of insulation layer 24, which is made of silicon nitride, is dipped into a solution of titanium tetrakis(dimethylamide) in hexane at a concentration of one millimole per liter and subsequently rinsed using hexane. Then, the field-effect transistor is heated for an hour at 400° C. while exposed to air. This overall process is repeated a total of three times. The result is a boundary layer 25, which is formed by a laterally even mono- to oligo-molecular layer of foreign element oxides in relation to the base material of insulation layer 24. Subsequently, a noble metal metallization is applied on produced boundary layer 25, as gate metallization 27.

When using metal amides, it is often impossible to initially completely remove all produced amines from the surface treated so as to form boundary layer 25 in a subsequent hydrolysis; for this reason, the field-effect transistor may subsequently be treated with a mixture of ethanol and hydrochloric acid at a 100:1 ratio.

Sensor element 10 produced in this manner is particularly suitable for determining gas components in gas mixtures such as in exhaust gases of internal combustion engines, heating systems, and in power plant applications. The sensor element is particularly suitable for detecting nitrogen oxides in combustion exhaust gases, e.g., for an on-board diagnosis in motor vehicles, or for monitoring exhaust-gas purification systems such as nitrogen oxide storage catalysts or SCR systems.

1-10. (canceled)

11. A sensor element of a gas sensor for determining gas components in a gas mixture, comprising:
a field-effect transistor having a source electrode, a drain electrode and a gate electrode;
wherein the gate electrode includes a gate metallization, which is in contact with one of an insulation layer and a semiconductor substrate of the field-effect transistor via a boundary layer, and
wherein the boundary layer is formed by modifying the surface of one of the insulation layer and the semiconductor substrate using at least one of metal alkoxides, metal amides, metal halogenides, and metal alkyls.

12. The sensor element of claim 11, wherein the insulation layer is made of silicon nitride.

13. The sensor element of claim 11, wherein the metal alkoxide is one of a titanium alkoxide and a germanium alkoxide.

14. The sensor element of claim 11, wherein the metal amide is one of a titanium(dialkylamide), a titanium tetradialkylamide, a titanium(bis(dimethylsilyl)amide, and a bismuth(bis(trimethylsilyl)amide.

15. The sensor element of claim 11, wherein the metal alkyl is a tetra alkyl germanium compound.

16. A method for producing a sensor element for gas sensors for determining gas components in a gas mixture, the method comprising:
integrating a boundary layer integrated in a gate electrode of a field-effect transistor; and
forming the boundary layer by treating a surface of one of an insulation layer and a semiconductor substrate with at least one of a metal alkoxide, a metal amide, a metal halogenide, and a metal alkyl;
wherein the sensor element includes the field-effect transistor having a source electrode, a drain electrode and a gate electrode, wherein the gate electrode includes a gate metallization, which is in contact with one of the insulation layer and the semiconductor substrate of the field-effect transistor via the boundary layer.

17. The method of claim 16, wherein following the treatment with the at least one of the metal alkoxide, the metal amide, the metal halogenide, and the metal alkyl, performing, in a second task, a hydrolysis and subsequently a dehydration of at least one of the applied metal alkoxide, the metal amide, the metal halogenide, and the metal alkyl.

18. The method of claim 16, wherein in a third task, performing a treatment with a mixture of a mineral acid in alcohol.

19. A sensor element of a gas sensor for determining gas components in a gas mixture of one of an internal combustion engine, a power plant, and a heating device, comprising:
a field-effect transistor having a source electrode, a drain electrode and a gate electrode;
wherein the gate electrode includes a gate metallization, which is in contact with one of an insulation layer and a semiconductor substrate of the field-effect transistor via a boundary layer, and
wherein the boundary layer is formed by modifying the surface of one of the insulation layer and the semiconductor substrate using at least one of metal alkoxides, metal amides, metal halogenides, and metal alkyls.

20. A sensor element of a gas sensor for determining gas components in a gas mixture for one of monitoring an operability of a NOx storage catalyst and an SCR exhaust-gas aftertreatment system, comprising:
a field-effect transistor having a source electrode, a drain electrode and a gate electrode;
wherein the gate electrode includes a gate metallization, which is in contact with one of an insulation layer and a semiconductor substrate of the field-effect transistor via a boundary layer, and
wherein the boundary layer is formed by modifying the surface of one of the insulation layer and the semiconductor substrate using at least one of metal alkoxides, metal amides, metal halogenides, and metal alkyls.
